(19) United States
(12) Patent Application Publication
(10) Pub. No.: US 2026/0164853 A1
(43) Pub. Date: Jun. 11, 2026

(54) METHOD FOR MANUFACTURING AN OPTOELECTRONIC SEMICONDUCTOR CHIP

(71) Applicant: AMS-OSRAM INTERNATIONAL GMBH, Regensburg (DE)

(72) Inventors: Christoph Klemp, Regensburg (DE); Stefan illek, Donaustauf (DE); Juanita N. Kurtin, Regensburg (DE); joseph A. Treadway, Portland, OR (US); Erik Johansson, Portland, OR (US); Andreas Ploessi, Regensburg (DE); Tansen Varghese, Regensburg (DE)

(21) Appl. No.: 18/708,543

(22) PCT Filed: Nov. 10, 2021
(86) PCT No.: PCT/US2021/058852

§ 371 Date: May 8, 2024

(51) Int. Cl. H10H 20/01; H10H 20/84

(52) U.S. Cl. CPC H10H 20/034; H10H 20/84

(57) ABSTRACT

In an embodiment a method for manufacturing an optoelectronic semiconductor chip includes providing a functional layer stack, wherein the functional layer stack comprises a first layer with a dopant of a first conductivity type, an active region arranged on the first layer, a second layer with a dopant of a second conductivity type arranged on the active region and a residual oxide layer arranged on at least one side surface of the first layer and/or the second layer and/or the active region, placing the functional layer stack in a liquid phase chemical reactor, removing oxygen from the at least one side surface in the liquid phase chemical reactor and growing an oxidatively stable layer on the at least one side surface in the liquid phase chemical reactor.

### CROSS-REFERENCE TO RELATED APPLICATIONS

This patent application is a national phase filing under section 371 of PCT/US 2021/058852, filed Nov. 10, 2021, which is incorporated herein by reference in its entirety.

### TECHNICAL FIELD

The present invention concerns a method for manufacturing an optoelectronic semiconductor chip as well as an intermediate product of a method for manufacturing an optoelectronic semiconductor chip.

### BACKGROUND

Epitaxial regrowth is an elegant method for the realization of concepts for high performance optoelectronic devices, e.g. distributed feedback (DFB) lasers, buried heterostructure lasers, and for the reduction of surface recombination in optoelectronic devices. Due to a desired structuring/patterning of the semiconductor layer stack of optoelectronic devices however oxidized surfaces may result along the processed surfaces of the semiconductor layer stack. These surfaces therefore need to be prepared before an epitaxial regrowth on this surfaces can be realized, as for a high performance and a stable operation (low degradation) of the optoelectronic devices the interfaces on which the regrowth takes place need to be defect free.

For III-V material systems without aluminum (e.g. InGaAsP) epitaxial regrowth is commercially established using wet chemical surface preparation within a tight time loop before regrowth. However, for aluminum containing materials (e.g. AlGaAs, InGaAIP) the issue of strong aluminum oxidation has prohibited the commercial use of epitaxial regrowth so far. Besides epitaxial regrowth the same issues are valid for surface preparation prior to any passivation layer deposition process (e.g. ALD, PVD).

A rarely used method to overcome these issues is to remove the oxidized surfaces within the regrowth tool by the introduction of a process gas that etches the semiconductor material (e.g. PCl₃, BCl₃). However, with this technique it's difficult to control the final geometry and to uniformly etch layer stacks with different material composition.

### SUMMARY

Embodiments provide an enhanced method for manufacturing high performance optoelectronic semiconductor chips.

Further embodiments provide an intermediate product of a method for manufacturing high performance optoelectronic semiconductor chips.

The concept of the inventors proposes to provide an epitaxially grown semiconductor stack comprising semiconductor layers, in particular InGaAP or AlGaAs, as well as an active region between the layers. The semiconductor stack further comprises a structuring/patterning as for example a mesa etching, which surface due to the material composition of the semiconductor stack, in particular containing aluminium, and the surrounding atmosphere tends to corrode. Thus, the surface of the structuring/patterning may, due to corrosion, comprise an oxide layer. To now initiate and/or complete a regrowth or a passivation on the surface of the structuring/patterning, the epitaxially grown semiconductor stack is introduced to a liquid phase chemical reactor and processed up to the point of exposing the surface to be regrown or passivated.

A liquid phase chemical reactor provides a colloidal growth methodology that allows facile control over alloying, the ability to direct growth of a particular crystal phase, and face selective growth, among other advantages.

After a semiconductor stack is prepared and structured, at this point the semiconductor stack is introduced to a wet chemical etch (for example, ammonia, HBr, Br₂ or a HF based etch) in a non-oxidizing solvent in order to remove any oxidation of the InGaAlP or AlGaAs surfaces. Thus, at least the oxygen of the oxide layer is removed from the surface to be regrown or passivated. This is done in a liquid phase oxygen-free (i.e. without O₂, H₂O) manner to preserve the surfaces once they are oxide-free. A suitable lattice and an electronically matched passivation layer (e.g. ZnSe, ZnS, or some alloy thereof) is then grown on the oxide-free sidewalls within the liquid phase chemical reactor preventing that “new” oxidation takes place at the surfaces.

After removal of oxide in the liquid-phase reactor, the semiconductor stack can be re-introduced to a standard epitaxial or thin-film deposition tool for material deposition (again with a tight time loop) to complete the regrowth or passivation process. Preferably, the passivation layer introduced by the colloidal chemical process can be decomposed at elevated temperature within the tool just before continuing the epitaxial regrowth or deposition process. Or the passivation layer introduced by the colloidal chemical process is naturally removed under the conditions of the continuing the epitaxial regrowth or deposition process. Hence the passivation layer introduced by the colloidal chemical process being a temporary passivation layer. Alternatively, the temporary passivation layer is removed in the epi reactor prior to regrowth by one or more process gases that modify and etch the temporary passivation layer material (e.g. with ZnEt₂, AsH₃, PH₃, HCl, PCl₃, BCl₃). As a further alternative, the passivation layer introduced by the colloidal chemical process can be formed as a permanent passivating layer without any further step of removing and regrowth, providing a passivation which has approximately the same properties as a conventionally grown passivation layer. The permanent passivation layer can for example comprise ZnSe, ZnS, or some alloy comprising those species.

One aspect of the invention therefore concerns the use of wet chemical and colloidal chemistry methods to clean the sensitive Al-containing sidewalls/remove the oxide and then initiate passivation layer deposition without exposing them to air or oxidizing ambient. A subsequent epitaxial regrowth of permanent surface-passivating semiconductor materials can then take place replacing the deposited temporary passivation layer within a standard epitaxy reactor (by regrowth, ALD, PVD), or the existing passivation layer is chosen to be the permanent passivation. In this case, the wet chemical steps may comprise separate oxide-removal steps, temporary passivation steps, and growth of permanent passivation layers (e.g. ZnSe, ZnS, or some alloy thereof) within the liquid phase chemical reactor.

The technical features necessary for implementation are the identification of suitable wet chemical etch reagents and air-(oxygen-, water-) free methods to remove the sidewall oxidation while preserving the layered structure, as well as identification of the necessary synthetic conditions to grow either an additional epitaxial semiconductor or any other suitable temporary passivation layer using the techniques and synthetic chemistry of colloidal quantum dots. In the case of etch and growth of a temporary passivation layer, the latter should be something that can be decomposed without residues in a standard epitaxial (or deposition) reactor, preferably by pyrolysis or by chemical reaction with process gases forming volatile reaction products, alternatively. In the case of etch and growth of an epitaxial semiconductor layer as a permanent passivation within the liquid phase chemical reactor, the growth material should comprise approximately the same properties as a conventionally grown passivation layer.

With the process sequence according to the invention a new method for sidewall oxide removal, temporary passivation and deposition i.e. of epitaxial regrowth of aluminum containing III-V material is disclosed, avoiding the use of heavily etching gases which can damage the surfaces of the sidewalls. Even for regrowth of aluminum-free material this technique can be favorable by providing a much more stable interface prior to regrowth (or passivation).

In some aspects, in a first step a sample comprising a stack of n semiconductor layers is provided where sidewalls have suffered oxidative damage, e.g., in a structuring process. In a second step the sample is placed in an enclosure (liquid phase chemical reactor) and ambient atmosphere is evacuated. The enclosure is in a third step back-filled with an etch reagent (e.g., NH₃ in ethanol, F-in organic solvents, HBr or Br2 neat or in nonreactive solvents, or citric acid solutions) which removes the damaged portions (residual oxide layer). Once the damaged portions are removed, the etch solution is removed, the enclosure can be brought back to atmospheric pressure and then is filled with an inert gas. Directly thereafter, reagents in solution phase or gas phase are added to the enclosure whereupon an oxidatively stable layer is grown conformally onto the sample, thus protecting it from further oxidative damage. In one embodiment a temporary passivating layer is thus formed, e.g. introducing sulfurization by an ammonium sulfide treatment step. This temporary protection provides greater flexibility in sample handling before performing a final regrowth/passivation process in a separate reactor. In another embodiment however a permanent passivating layer is formed, e.g. ZnSe growth by using a Zn carboxylate and Se.

The term “oxidatively stable layer” can be understood in such a way that the layer can to a certain degree still oxidize with enough exposure to atmosphere, but much slower than for example a passivation layer of a semiconductor material. semiconductor Agreed. The oxidatively stable layer can thus for example be a oxidatively protective layer or a oxidation-resistive layer. In some aspects, the passivation layer comprises two or more components. For example a sulfide treatment of the etched stack may be followed by for example a thin conformal layer coating of SiO₂ deposited via PECVD, Al₂O₃/SiO₂ deposited via ALD/PVD or SiNₓ deposited via ECR-CVD.

In some aspects, a method for manufacturing an optoelectronic semiconductor chip comprises a step of providing a functional layer stack the functional layer stack comprising:
a first layer with a dopant of a first conductivity type;
an active region arranged on the first layer;
a second layer with a dopant of a second conductivity type arranged on the active region; and
a residual oxide layer arranged on at least one side surface of the first layer and/or the second layer and/or the active region;

The method further comprises the steps of the placing the functional layer stack in a liquid phase chemical reactor, removing oxygen from the at least one side surface, and growing an oxidatively stable layer on the at least one side surface.

The residual oxide layer can thereby be a layer or a formation of corroded or oxidated particles, structures and/or reaction products on at least one side surface of the layer stack. Residual in this context can thereby be understood as a whole layer of corroded or oxidated particles, structures and/or reaction products resulting for example from a structuring of the layer stack under atmospheric conditions but can also be understood as the remainings of a layer of corroded or oxidated particles, structures and/or reaction products already being processed, which still comprises oxidated particles.

In some aspects, the step of removing oxygen from the at least one side surface is a removal, in particular complete removal, of the residual oxide layer from the at least one side surface, in particular by a wet etching process. The functional layer stack is therefore for example introduced into a non-oxidizing solvent containing for example ammonia, HBr, Br2 or a HF based etch in order to remove any oxidation of the side surfaces of the layer stack. This is done in a liquid phase oxygen-free (i.e. without O2, H2O) manner to preserve the surfaces once they are oxide-free.

In some aspects in addition or as an alternative to oxygen, carbon and/or Sulfur can be removed from the at least one side surface which can for example result from a structuring of the layer stack.

In some aspects, the step of removing oxygen from the at least one side surface is not a step of completely removing the residual oxide layer but only of the oxygen within the residual oxide layer. Thus, oxide bonds within the residual oxide layer are broken by use of for example a solvent and the released oxygen then reacts with a reactant within the solvent and is removed with the solvent from the residual oxygen layer.

In some aspects, the step of providing the functional layer stack comprises an epitaxially growing of the first layer, the second layer and the active region between the first and the second layer, in particular by vapour deposition. In particular, the first layer, the second layer and the active region between the first and the second layer are grown in an epi reactor, a deposition chamber, or in a front end by use of a vapour deposition process.

In some aspects, the step of providing a functional layer stack comprises a structuring/patterning as for example a mesa etching of the functional layer stack, wherein the residual oxide layer is formed along at least a portion of the structuring due to the structuring, in particular during and/or after the structuring process.

In some aspects, the oxidatively stable layer is a temporary protection layer, which is in a subsequent step replaced by a permanent protection layer of for example a semiconductor material. It is however also possible, that the oxidatively stable layer is already a permanent protection layer of a material which is grown in liquid phase. In such a case a subsequent removal of the temporary protection layer and growth of a permanent protection layer may become obsolete.

In some aspects, the temporary protection layer has a thickness of less than 5 nm. In case of a permanent protection layer this may however has a thickness of approximately 10 nm to 100 nm.

In some aspects, the method further comprises a step of placing the functional layer stack in an epi reactor or a deposition chamber after the step of growing an oxidatively stable layer, in particular temporary protection layer, to on the one hand remove the temporary protection layer and on the other hand grow a permanent protection layer.

In some aspects, the method further comprises a step of removing the temporary protection layer, and in some aspects the method further comprises a step of growing or depositing a permanent protection layer on the at least one side surface. The step of growing or depositing the permanent protection layer is in particular performed by use of a vapour deposition process.

In some aspects, the method further comprises a step of annealing the oxidatively stable layer in case it being the permanent protection layer or a step of annealing the permanent protection layer after being grown on the at least one side surface in the epi-reactor after removal of the oxidatively stable layer. Instead of annealing or in addition to it further chemical treatments are conceivable as well.

In some aspects, the method further comprises a step of generating a vacuum in the liquid phase chemical reactor in that ambient atmosphere is evacuated in the reactor.

In some aspects, the step of growing an oxidatively stable layer comprises the exposure to an inert gas and an addition of desired reagents/reactants. The oxidatively stable layer may thus comprises an initial material selected from the group consisting of:
Halides such as fluorine (F), chloride (Cl), bromine (Br) and iodine (I);
Amines such as hexamethyldisilazan (HMDS), in particular without N—H bonds;
Organic amines and imines such as octylamine, di-octylamine and pyridine;
Sulfides, in particular without S—H bonds;
Boranes such as BH₃;
Thiols;
Carboxylic, phosphonic, and phosphinic acids such as oleic acid, octadecylphosphonic acid and tetradecylphosphinic acid;
Phosphates and salts of phosphate such as hydroxy-apatite;
Organic phosphines such as tri-octylphosphine and di-octylphosphine;
Multidentate and mixed organics such as acetylacetonate, lysine or oligo-lysine, ortho-catechols, 4,4′-bypyridine, EDTA and ethylenediamine;
Multidentate polymers such as polyethylene imine and polyacrylic acid; and
Semiconductor materials like metal chalcogenides where metals may be Cd or Zn, and chalcogens may be Se or S.

By the term “initial material” in particular the main components of the oxidatively stable layer are to be understood, which when growing or depositing the oxidatively stable layer are used. In case of the oxidatively stable layer being a temporary passivation layer the initial material can for example even be present on the at least one side surface in form of residuals, after removal of the temporary passivation layer.

The optoelectronic semiconductor chip is, for example, a radiation-emitting optoelectronic semiconductor chip. For example, the semiconductor chip may be a light emitting diode (LED) chip or a laser chip. The optoelectronic semiconductor chip may generate light during operation. In particular, it is possible that the optoelectronic semiconductor chip generates light in the spectral range from UV radiation to light in the infrared range, or in particular visible light. Alternatively, it is possible that the optoelectronic semiconductor chip is a radiation-detecting semiconductor chip, for example a photodiode.

The optoelectronic chip may for example comprise edge lengths of less than 100 μm, or less than 40 μm, and in particular less than 10μm. The optoelectronic semiconductor chip can thus for example be a μLED (LED for light emitting device, μLED for micro-LED) or a μLED-chip.

In some aspects, an optoelectronic semiconductor chip, in particular an intermediate product of a method for manufacturing an optoelectronic semiconductor chip comprises a functional layer stack comprising a first layer with a dopant of a first conductivity type, an active region arranged on the first layer and a second layer with a dopant of a second conductivity type arranged on the active region. The optoelectronic semiconductor chip further comprises an oxidatively stable layer arranged on at least one side surface of the first layer and/or the second layer and/or the active region, wherein the oxidatively stable layer comprises an initial material which grown in liquid phase or is at least suitable to be grown in liquid phase.

In some aspects, the oxidatively stable layer comprises an initial material selected from the group consisting of:
Halides such as fluorine (F), chloride (CI), bromine (Br) and iodine (I);
Amines such as hexamethyldisilazan (HMDS), in particular without N-H bonds;
Organic amines and imines such as octylamine, di-octylamine and pyridine;
Sulfides, in particular without S-H bonds;
Boranes such as BH₃;
Thiols;
Carboxylic, phosphonic, and phosphinic acids such as oleic acid, octadecylphosphonic acid and tetradecylphosphinic acid;
Phosphates and salts of phosphate such as hydroxy-apatite;
Organic phosphines such as tri-octylphosphine and di-octylphosphine;
Multidentate and mixed organics such as acetylacetonate, lysine or oligo-lysine, ortho-catechols, 4,4′-bypyridine, EDTA and ethylenediamine;
Multidentate polymers such as polyethylene imine and polyacrylic acid; and
Semiconductor materials like metal chalcogenides where metals may be Cd or Zn, and chalcogens may be Se or S.

In some aspects, the oxidatively stable layer is a temporary protection layer, which can in a subsequent step replaced by a permanent protection layer of for example a semiconductor material. It is however also possible, that the oxidatively stable layer is already a permanent protection layer of a material which is grown in liquid phase. In such a case a subsequent removal of the temporary protection layer and growth of a permanent protection layer may become obsolete.

In case of the oxidatively stable layer being a temporary protection layer it can have a thickness of less than 5 nm. In case of the oxidatively stable layer being a permanent protection layer it can have a thickness of approximately 10 nm to 100 nm or even more.

### BRIEF DESCRIPTION OF THE DRAWINGS

In the following, embodiments of the invention will be explained in more detail with reference to the accompanying drawings.

FIG. 1 shows steps of a method for manufacturing an optoelectronic semiconductor chip;

FIG. 2 shows steps of a method for manufacturing an optoelectronic semiconductor chip according to some aspects of the invention; and

FIG. 3 shows detailed view of steps of a method for manufacturing an optoelectronic semiconductor chip according to some aspects of the invention.

### DETAILED DESCRIPTION OF ILLUSTRATIVE EMBODIMENTS

The present disclosure will now be described more fully hereinafter with reference to the accompanying drawings, in which exemplary embodiments of the disclosure are shown. The disclosure may, however, be embodied in many different forms and should not be construed as limited to the embodiments set forth herein; rather, these embodiments are provided for thoroughness and completeness. Like reference characters refer to like elements throughout the description. The drawings are not necessarily to scale and certain features may be exaggerated in order to better illustrate and explain the exemplary embodiments of the present disclosure.

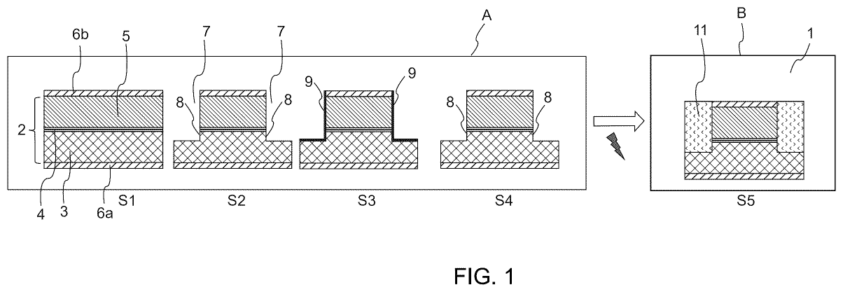

FIG. 1 shows steps of a method for manufacturing an optoelectronic semiconductor chip 1. In a first step S1 a functional layer stack 2 is provided comprising a first layer 3 with a dopant of a first conductivity type, an active region 4 arranged on the first layer 3, and a second layer 5 with a dopant of a second conductivity type arranged on the active region 4. In addition, a first and a second electrically conductive contact layer 6a, 6b is arranged on the first layer 3 and the second layer 5 to electrically contact the optoelectronic semiconductor chip 1. In a second step S2 the functional layer stack 2 as well as the electrically conductive contact layers 6a, 6b are structured/etched in a desired manner. Exemplarily here a structuring 7 in form of a mesa shape/etch is shown, so that sidewalls 8 of the first layer 3, the second layer 5 and the active region 4 result.

Due to the structuring and in particular due to the exposure to Oxygenated environment during the step of structuring the sidewalls 8 have suffered oxidative damage so that a oxide layer 9 results along them as shown in step S3. In particular for aluminum containing materials (e.g. AlGaAs, InGaAIP) the issue of strong aluminum oxidation is a well known problem when structuring. Thus, the surface of the structuring/patterning may, due to corrosion, comprise an oxide layer.

In a fourth step S4, the oxide layer 9 is removed by for example wet chemical etching as a preparation step of growing a passivation layer 11 in step S5 in an epi reactor B. However as indicated by the lightning the transfer from the front end A to the epi reactor B needs to be very fast as well as the time after etching the oxide layer 9 and growing or depositing the passivation layer needs to be very short to prevent “new” oxidation of the sidewalls 8 in the meantime. In particular the transfer from the front end A to the epi reactor B is very critical in particular in terms of environment and time and thus the demands on this transfer step are at least for a commercial use too high to use such a method for manufacturing optoelectronic semiconductor chips 1 containing aluminum within the functional layer.

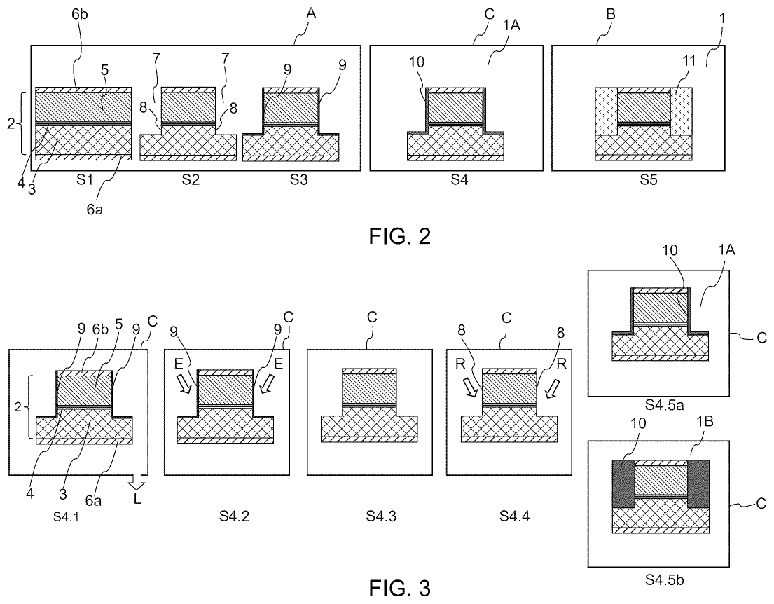

FIGS. 2 and 3 provide an enhanced method for manufacturing optoelectronic semiconductor chips 1 according to some aspects of the invention. Thereby the oxide layer 9 is removed in a liquid phase chemical reactor C, in particular oxygen-free reactor, and directly after removing oxide layer 9 an oxidatively stable layer 10 is deposited on the critical sidewalls within the same reactor to prevent a “new” oxidation of the sidewalls 8.

Steps S1 to S3 of FIG. 2 correspond to the steps S1 to S3 already described above. Step S4 of FIG. 1 is however replaced by a different step S4 which in contrast to FIG. 1 takes place in a liquid phase chemical reactor C and not in the front end A. Within the liquid phase chemical reactor C the oxide layer 9 is removed and directly after removing oxide layer 9 an oxidatively stable layer 10 is deposited on the critical sidewalls. The oxidatively stable layer 10 is then in an optional step S5 re-introduced to a standard epi reactor B to complete the regrowth or passivation process. Preferable, the oxidatively stable layer 10 can be decomposed at elevated temperature within the epi reactor B just before continuing the epitaxial regrowth or deposition process of a permanent passivation layer 11. Hence the oxidatively stable layer 10 is in one embodiment a temporary passivation layer. The temporary passivation layer can however also be removed in the epi reactor B prior to regrowth by one or more process gases that modify and etch the temporary passivation layer material (e.g. with ZnEt₂, AsH₃, PH₃, HCl, PCl₃, BCl₃). The permanent passivation layer 11 can for example be of a semiconductor material.

FIG. 3 shows a more detailed view of step S4 as well as an alternative embodiment with the oxidatively stable layer 10 not being a temporary passivation layer but already a permanent passivation layer 10 (see step S4.5b. The material oxidatively stable layer 10 is therefore grown/deposited with a greater thickness and already serves as a permanent passivation layer making the last step S5 of FIG. 2 obsolete.

In a first sub step S4.1 the layer stack 2 is placed into the liquid phase chemical reactor C and ambient atmosphere is evacuated in the reactor. This is indicated by the small arrow at the bottom shown the air L in the reactor being removed.

The reactor is then in a second sub step S4.2 after being brought back to atmospheric pressure back-filled with an etch solution E (e.g., NH₃ in ethanol, F-in organic solvents, HBr or Br2 in organic solvents, or citric acid solutions) which removes the oxide layer 9. The etch solution E is removed and the sidewalls of the layer stack are free from oxide as shown in sub step S4.3. The reactor is then in a further sub step S4.4 filled with an inert gas and directly thereafter, reagents R in solution phase or gas phase are added to the enclosure whereupon the oxidatively stable layer 10 is grown conformally onto the sidewalls 8 of the layer stack 2, thus protecting it from further oxidative damage.

As already indicated the oxidatively stable layer 10 is in a first alternative a temporary passivation layer (see step S4.5a), whereas the oxidatively stable layer 10 is in a second alternative already a permanent passivation layer (see step S4.5b).

1.-15. (canceled)

16. A method for manufacturing an optoelectronic semiconductor chip, the method comprising:
providing a functional layer stack, wherein the functional layer stack comprises a first layer with a dopant of a first conductivity type, an active region arranged on the first layer, a second layer with a dopant of a second conductivity type arranged on the active region and a residual oxide layer arranged on at least one side surface of the first layer and/or the second layer and/or the active region;
placing the functional layer stack in a liquid phase chemical reactor;
removing oxygen from the at least one side surface in the liquid phase chemical reactor; and
growing an oxidatively stable layer on the at least one side surface in the liquid phase chemical reactor.

17. The method according to claim 16, wherein removing the oxygen from the at least one side surface comprises removing the residual oxide layer from the at least one side surface in a wet etching process.

18. The method according to claim 16, wherein removing the oxygen from the at least one side surface comprises removing the oxygen from the residual oxide layer by breaking oxide bonds in the residual oxide layer and having the oxygen react with a reactant component.

19. The method according to claim 16, wherein providing the functional layer stack comprises epitaxially growing the first layer, the second layer and the active region between the first and the second layer by vapor deposition.

20. The method according to claim 16, wherein providing the functional layer stack comprises structuring the functional layer stack, wherein the residual oxide layer is formed along at least a portion of a resulting structure due to the structuring.

21. The method according to claim 16, wherein the oxidatively stable layer is a temporary protection layer.

22. The method according to claim 21, wherein the temporary protection layer has a thickness of less than 5 nm.

23. The method according to claim 21, further comprising placing the functional layer stack in an epi reactor or a deposition chamber after the growing the oxidatively stable layer.

24. The method according to claim 21, further comprising removing the oxidatively stable layer.

25. The method according to claim 24, further comprising growing or depositing a permanent protection layer on the at least one side surface.

26. The method according to claim 16, further comprising annealing the oxidatively stable layer or a permanent protection layer.

27. The method according to claim 16, wherein growing the oxidatively stable layer comprises an exposure to an inert gas and an addition of desired reactants.

28. The method according to claim 16, wherein the oxidatively stable layer comprises an initial material selected from the group consisting of halides, amines, organic amines, organic imines, sulfides, boranes, thiols, carboxylic acids, phosphonic acids, phosphinic acids, phosphates and salts of phosphates, organic phosphines, multidentate organics, mixed organics, and multidentate polymers.

29. An optoelectronic semiconductor chip comprising:
a functional layer stack comprising:
a first layer with a dopant of a first conductivity type;
an active region arranged on the first layer; and
a second layer with a dopant of a second conductivity type arranged on the active region; and
an oxidatively stable layer arranged on at least one side surface of the first layer and/or the second layer and/or the active region,
wherein the oxidatively stable layer comprises an initial material, which is grown in liquid phase.

30. The optoelectronic semiconductor chip according to claim 29, wherein the oxidatively stable layer comprises the initial material selected from the group consisting of halides, amines, organic amines, organic imines, sulfides, boranes, thiols, carboxylic acids, phosphonic acids, phosphinic acids, phosphates and salts of phosphates, organic phosphines, multidentate organics, mixed organics, and multidentate polymers.
